(19) United States
(12) Patent Application Publication
(10) Pub. No.: US 2023/0415268 A1
(43) Pub. Date: Dec. 28, 2023

(54) DEVICE AND METHOD FOR IMPRINTING METAL MEMBER USING EXTERNAL ELECTRIC FIELD AND IR BAND LASER TRANSMISSIVE MOLD

(71) Applicant: Industry-Academic Cooperation Foundation Yonsei University, Seoul (KR)

(72) Inventors: Shinill KANG, Seoul (KR); Run Jia HAN, Seoul (KR)

(21) Appl. No.: 17/478,763

(22) Filed: Sep. 17, 2021

(51) Int. Cl. B23K 26/352; B23K 26/70; B23K 26/60; B21J 1/06

(52) U.S. Cl. CPC B23K 26/352; B21J 1/06; B23K 26/60; B23K 26/70

(57) ABSTRACT

A device and method for imprinting a metal member using an external electric field and an IR band laser transmissive mold method are provided. The device includes a laser-beam generating device spaced apart from a surface of the metal member that is to be imprinted, and generating a laser beam of an IR band to radiate the laser beam onto the metal member surface, an electric-field forming device forming an electric field between both side surfaces of the metal member perpendicular to a direction in which the laser beam is incident, and a mold made of a material through which the laser beam may be transmitted, having on a surface thereof a fine pattern to form the fine pattern on the metal member surface, and performing an imprinting operation while coming into contact with the metal member surface that is softened by irradiation of the laser beam.

### BACKGROUND OF THE INVENTION

### 1. Field of the Invention

The present disclosure relates to a device and a method for imprinting a metal member surface using an external electric field and an IR transmissive mold. More particularly, the present disclosure relates to a device and a method for imprinting a metal member using an external electric field and an IR band laser transmissive mold, which are intended to effectively transfer a pattern to a surface of the metal member using the IR band laser transmissive mold, by applying the external electric field to the metal member that is to be imprinted and thereby increasing the absorptivity of an IR laser on the metal member surface.

### 2. Description of Related Art

Since a metal material has good physical and chemical durability, it is applied to important elements in modern industry. Since a micro- or nano-scale structure formed on a metal member may impart various functions to the surface of the metal member, many studies have been conducted in this field.

As a method for forming a micro- or nano-structure on the metal member, a method of directly processing a metal member, such as photolithography or nano-imprint lithography, has been proposed. However, the photolithography method is problematic in that several processes including a mask fabrication process, an exposure process, and an etching process should be performed, so the process is complicated and the cost for forming the device is also high, and consequently mass production thereof is not easy.

Further, the nano-imprint lithography is problematic in that a manufacturing cost thereof is high to realize the large area of a nano mold, and mass production thereof is difficult due to a residual layer of a nano pattern. As another technology, a technology of directly imprinting metal using ultra-high pressure has been proposed. However, this is problematic in that a nano pattern may not be filled, and energy required for the process is very high, thus making it difficult to implement the direct imprinting technology.

Furthermore, there has been proposed a method of directly processing a metal material. However, this is problematic in that a processing speed is very slow, so productivity is limited, and the size of a pattern that may be processed is determined by a processing tool, so the size of a pattern that may be implemented is limited.

In order to overcome the above-mentioned problems of the related art, an imprinting technology using an IR laser and an IR laser transmissive mold has been recently proposed by the inventors of the present disclosure. However, the metal thermal imprinting process using the IR transmissive mold is problematic in that the reflectance of a metal material is usually high in an IR region, so IR energy is not effectively absorbed by a surface of a metal member, and consequently the surface of the metal member does not reach temperature required for imprinting.

Documents of Related Art (Patent Document 1) Korean Patent No. 10-1142847 (Apr. 27, 2012).

### SUMMARY OF THE INVENTION

Accordingly, the present disclosure has been made keeping in mind the above problems occurring in the related art, and an objective of the present disclosure is to provide a device and a method for imprinting a metal member using an external electric field and an IR band laser transmissive mold, in which the reflectivity of an IR laser is reduced on a metal member surface and the absorptivity of laser energy is increased by applying the external electric field to the metal member that is to be imprinted, so a pattern is effectively transferred to the metal member surface through the laser transmissive mold, in a state where the metal member surface is softened by heating.

In order to achieve the objective of the present disclosure, the present disclosure provides a device for imprinting a metal member using an external electric field and an IR band laser transmissive mold, the device including a laser-beam generating device spaced apart from a surface of the metal member that is to be imprinted, and generating a laser beam of an IR band to radiate the laser beam onto the surface of the metal member; an electric-field forming device forming an electric field between both side surfaces of the metal member perpendicular to a direction in which the laser beam is incident; and a mold made of a material through which the laser beam may be transmitted, having on a surface thereof a fine pattern to form the fine pattern on the surface of the metal member, and performing an imprinting operation while coming into contact with the surface of the metal member that is softened by irradiation of the laser beam.

The laser beam radiated onto the surface of the metal member may be an IR band CO₂ laser beam.

The fine pattern formed on the surface of the mold may be a fine pattern of a micro- or nano-scale structure.

The electric-field forming device may include a pair of electrode plates arranged on both side surfaces of the metal member to face each other, and charged through a current applied by an external device to form an electric field around the metal member; a support plate spaced apart from the electrode plates to support the metal member; and a support frame fixed on the support plate to support each of the electrode plates.

The pair of electrode plates may be disposed to be parallel to a direction in which the laser beam is incident.

The device may further include a heater disposed between the metal member and the support plate to previously heat the metal member before the laser beam is incident.

The support plate may be formed of a heat insulating material.

Further, the present disclosure provides a method for imprinting a metal member using an external electric field and an IR band laser transmissive mold, the method including forming an electric field between both side surfaces of the metal member that is to be imprinted; softening a surface of the metal member to be suitable for imprinting, by generating an IR band laser beam from a laser-beam generating device spaced apart from the surface of the metal member and then radiating the laser beam onto the surface of the metal member perpendicular to both side surfaces of the metal member; and forming a fine pattern on the surface of the metal member by pressing the softened metal member surface with the laser transmissive mold having a fine pattern.

The laser beam radiated onto the surface of the metal member may be an IR band CO2 laser beam.

The fine pattern formed on the mold may be a fine pattern of a micro- or nano-scale structure.

The method may further include previously heating the metal member through a heater, before the laser beam is radiated onto the surface of the metal member.

According to the present disclosure, an external electric field is applied to the periphery of a metal member that is to be imprinted, to rearrange free electrons in the metal member, thereby reducing the density of the free electrons on a metal member surface and consequently increasing the absorptivity of a laser beam, and a fine pattern can be effectively transferred to the metal member surface, which is softened by heating through the laser beam, using a mold.

In addition, the present disclosure is advantageous in that a process time is shortened and a large-area process is realized by scanning a laser beam over an entire area of a metal member while a mold and the metal member come into contact with each other, in a state where an electric field is applied to the periphery of the metal member.

### BRIEF DESCRIPTION OF THE DRAWINGS

The above and other objectives, features, and other advantages of the present disclosure will be more clearly understood from the following detailed description when taken conjointly with the accompanying drawings, in which:

FIG. 1 is a diagram illustrating the configuration of a device for imprinting a metal member in accordance with the present disclosure.

FIG. 2 is a sectional view illustrating a state in which an external electric field is formed on the metal member that is to be imprinted, a laser beam is radiated onto the metal member to soften the metal member, and then a surface of the softened metal member is pressed with a mold, thus forming a nano pattern.

FIG. 3 is a conceptual diagram illustrating the arrangement of free electrons and holes in the metal member when an external electric field is applied to the metal member.

FIG. 4 is a conceptual diagram illustrating a mechanism in which a laser beam is reflected by free electrons distributed on the surface of the metal member when no external electric field is formed around the metal member.

FIG. 5 is a conceptual diagram illustrating a mechanism in which the reflectivity of the laser beam is reduced through the rearrangement of the free electrons and the holes in the metal member when the external electric field is formed around the metal member, so laser absorptivity is increased.

FIG. 6 is a block diagram sequentially illustrating a method for imprinting a metal member using a device for imprinting a metal member in accordance with the present disclosure.

### DETAILED DESCRIPTION OF THE INVENTION

Hereinafter, embodiments of the present disclosure will be described in detail with reference to the accompanying drawings so that those skilled in the art can easily carry out the present disclosure.

However, the present disclosure may be implemented in several different forms and is not limited to embodiments described herein. In addition, it should be noted that the same reference numerals designate the same components throughout the detailed description.

Hereinafter, a device and a method for imprinting a metal member according to an embodiment of the present disclosure will be described in detail with reference to the accompanying drawings.

A conventional metal thermal imprinting process using an IR band laser transmissive mold is problematic in that the reflectance of a metal material is high in an IR region, so IR energy is not absorbed well by a surface of a metal member, and consequently the surface of the metal member does not reach temperature required for imprinting.

However, according to the present disclosure, the absorptivity of an IR band laser is increased by applying an external electric field to a metal material so as to increase energy absorptivity for the metal material with high reflectivity in an IR band, and a fine pattern is transferred from a mold to the surface of a metal member heated by absorbed laser, so a process time is short, and a large-area process is realized by scanning a laser beam over an entire area.

To this end, according to the present disclosure, in order to increase the laser absorptivity of an object that is to be imprinted, i.e. a metal material having relatively high reflectivity for an IR band laser, the distribution of free electrons in the metal material is changed using an external electric field, and photons of the laser and bounding electrons of the metal interact with each other, so the absorptivity of the IR laser can be increased on the metal member surface, and thereby a fine pattern of a micro- or nano-scale can be transferred to the metal member surface which is heated for a short period of time and is softened, using the transmissive mold.

In particular, the present disclosure provides a device and a method for imprinting a metal member using an external electric field and an IR band laser transmissive mold, in which a large-area process is realized by scanning a laser beam over an entire area of a metal member while a mold and the metal member coming into contact with each other, in a state where an electric field is applied to the periphery of the metal member.

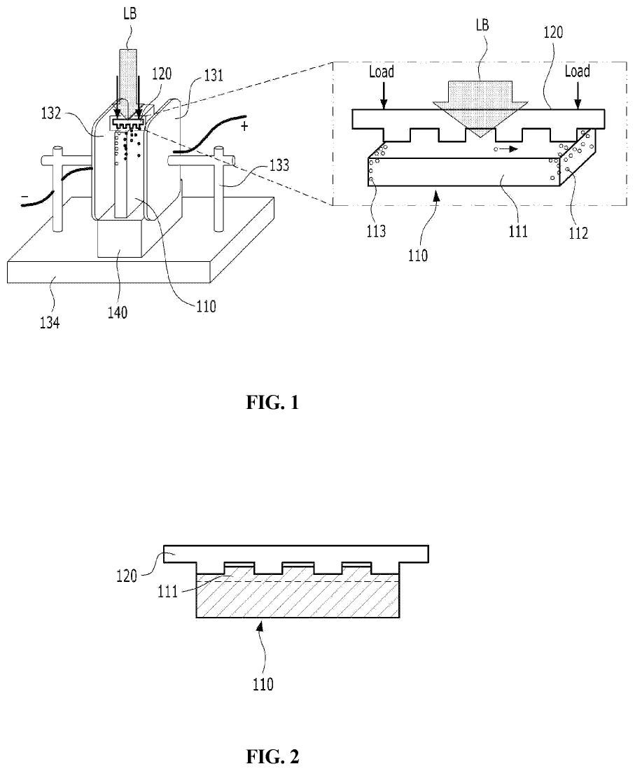

FIG. 1 is a diagram illustrating the configuration of a device for imprinting a metal member using an external electric field and an IR band laser transmissive mold in accordance with an embodiment of the present disclosure.

Referring to FIG. 1, the device for imprinting the metal member in accordance with an embodiment of the present disclosure includes a laser-beam generating device that generates a laser beam LB of an IR band, an electric-field forming device that forms an electric field around a metal member 110 that is to be imprinted, and a laser transmissive mold 120 that performs a fine patterning operation of a micro- or nano-scale pattern while coming into contact with a surface 111 of the metal member.

The laser-beam generating device (not shown) is disposed above the metal member 110, which is to be imprinted, to generate the laser beam LB of an IR wavelength band and thereby cause the laser beam to be incident onto the surface of the metal member 110.

In this regard, the laser radiated onto the surface of the metal member 110 through the laser-beam generating device may be an IR band CO₂ laser that may generate strong energy of a large wavelength.

The electric-field forming device forms an electric field around the metal member 110 to change the distribution of free electrons 112 in the metal member 110, thereby increasing the absorptivity of the laser beam LB that is incident onto the surface 111 of the metal member. Such an electric-field forming device will be described later in detail.

The laser transmissive mold 120 may have on a lower surface thereof a fine pattern of a micro- or nano-structure to form the fine pattern on the surface 111 of the metal member. In this regard, the laser transmissive mold 120 may be made of a relatively transparent and transmissive material to allow the laser beam LB of the IR band radiated from an upper position to be easily transmitted.

FIG. 2 is a sectional view illustrating a state in which the external electric field is formed on the metal member 110 that is to be imprinted, the laser beam is radiated onto the metal member to soften the metal member, and then the surface 111 of the softened metal member is pressed with the laser transmissive mold 120, thus forming a fine pattern.

As shown in FIG. 2, the laser transmissive mold 120 may press down the surface 111 of the metal member that is softened due to temperature increased by the irradiation of the laser beam LB, thus forming the fine pattern of the micro- or nano-structure on the surface of the metal member 110.

A heater 140 may be installed between the metal member 110 and a support plate 134, and may provide thermal energy to heat the surface 111 of the metal member before the laser beam LB is radiated onto the surface of the metal member 110.

In other words, by previously heating the metal member 110 through the heater 140 prior to radiating the laser beam LB onto the surface of the metal member 110, the softening of the metal member 110 is promoted, thus allowing the fine pattern to be formed on the surface 111 of the metal member within a short period of time. Such a heater 140 may be optionally provided as necessary.

The electric-field forming device includes a pair of electrode plates 131 and 132 that are disposed to be parallel to each other with the metal member 110 being interposed therebetween, the support plate 134 that supports the bottom of the metal member 110, and a support frame 133 that is fixed on the support plate 134 to support the electrode plates 131 and 132.

The electrode plates 131 and 132 have a size and an area that may sufficiently cover both side surfaces of the metal member 110. Since the electrode plates 131 and 132 are arranged to be parallel to each other while facing each other and being spaced apart from both side surfaces of the metal member 110 by a predetermined distance, both the electrode plates 131 and 132 are arranged to be parallel to a direction in which the laser beam LB is incident.

The support plate 134 serves to support the bottom of the metal member 110. In the case of having the heater 140 as in the embodiment of the present disclosure, the heater 140 and the metal member 110 are sequentially stacked on the support plate 134, so the metal member 110 is supported on the support plate 134 via the heater 140. In the case of having no heater 140, the metal member 110 may be supported while being in direct contact with the support plate 134.

In this case, the support plate 134 may be preferably formed of a heat insulating material capable of preventing heat transfer so that heat transfer does not occur between the support plate and the metal member 110 or the heater 140.

The support frame 133 is coupled to both the electrode plates 131 and 132 while being perpendicularly fixed on the support plate 134, thus supporting the electrode plates 131 and 132 to be parallel to each other.

FIG. 3 illustrates the arrangement of the free electrons and the holes in the metal member 110 when the external electric field is applied to the metal member 110.

As shown in FIG. 3, the electrode plates 131 and 132 are electrically connected to an external power supply device. Thus, when current is applied to the electrode plates 131 and 132, one electrode plate 131 may be charged with a positive (+) current and the other electrode plate 132 may be charged with a negative (−) current, so a capacitor electric field may be formed between both the electrode plates 131 and 132.

If the capacitor electric field is formed between both the electrode plates 131 and 132 as such, the free electrons 112 and the holes 113 in the metal member 110 are moved towards both the electrode plates 131 and 132, respectively, so the number of the free electrons 112 settled in the surface 111 of the metal member is reduced, and thereby the density of the free electrons 112 is reduced on the surface 111 of the metal member onto which the laser beam LB is to be radiated.

Further, as the density of the free electrons 112 is reduced on the surface 111 of the metal member, most of the photons of the laser beam LB incident into the surface 111 of the metal member are absorbed into the metal member 110 without being disturbed by the free electrons 112, and electron energy is transmitted to ions and a lattice by an electron-phonon interaction, so the surface temperature of the metal member 110 is increased while thermal equilibrium is created between an electron system and a lattice system. Further, as the surface temperature of the metal member 110 increases, the surface 111 of the metal member starts to be softened and thereby be suitable for forming the fine pattern.

As such, if the surface 111 of the metal member is softened to be suitable for the imprinting operation by the irradiation of the laser beam LB, the laser transmissive mold 120 positioned above the metal member 110 is moved downwards to transfer the fine pattern of the micro- or nano-structure to the surface 111 of the softened metal member.

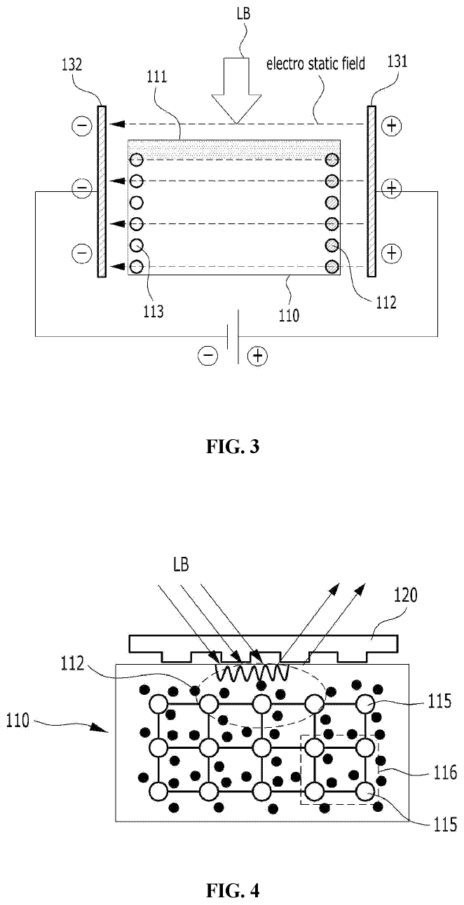

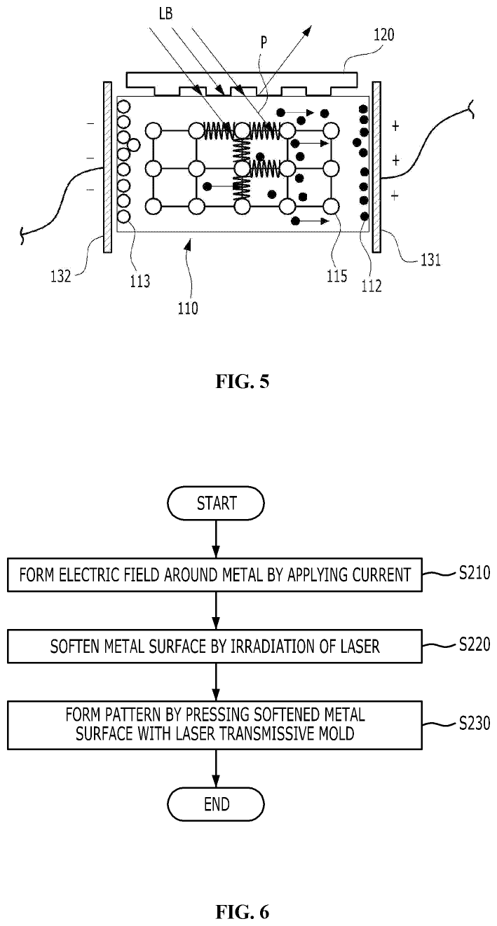

FIGS. 4 and 5 illustrate a mechanism in which a laser beam is absorbed and reflected by the surface of the metal member 110 depending on whether the external electric field is formed around the metal member 110.

First, FIG. 4 illustrates a mechanism in which the laser beam LB is reflected by the free electrons 112 distributed on the surface 111 of the metal member when no external electric field is formed around the metal member 110.

Generally, when the laser beam interacts with the surface of a target material, the photon of the laser beam starts to be absorbed in the form of electrical and vibrational excitation of atoms present in the material. Subsequently, the energy transmitted to the lattice phonon is converted into heat, which is then dissipated into surrounding atoms. As more and more photons are absorbed into the material, the temperature of the material rises. This process leads to knock on effects.

In particular, since ions in the metal material are too heavy to follow the vibrating electric field of laser radiation, they do not directly absorb the laser energy. Therefore, the laser energy is usually absorbed by free electrons and bounding electrons in the metal material. However, since most photons of the laser beam are blocked by actively vibrating free electrons on the metal surface due to the vibration frequency of free electrons present in electron cloud (gas) of the metal material surface, the absorptivity of the laser beam is significantly reduced on the metal material surface.

In other words, as shown in FIG. 4, the laser beam LB passes through the mold 120 made of a laser transmissive material and then reaches the surface of the metal member 110, but most of the laser beam is reflected due to the free electrons 112 of the metal distributed over the surface of the metal member 110. Thus, the absorptivity of the laser beam LB is lowered, so temperature required for imprinting is not easily reached.

FIG. 5 illustrates a mechanism in which the reflectivity of the laser beam LB is reduced through the rearrangement of the free electrons 112 and the holes 113 in the metal member 110 when the external electric field is formed around the metal member 110, so laser absorptivity is increased.

As shown in FIG. 5, when current flows through both the electrode plates 131 and 132 disposed around the metal member 110 to form a capacitor electric field, a Coulomb force (electrostatic force) is generated between both the electrode plates 131 and 132 of flat capacitors that face each other.

Then, the metal member 110 positioned between both the electrode plates 131 and 132 is subjected to an electric tension through the Coulomb force. Thus, a large number of free electrons 112 are arranged on the surface 111 of the metal member along an applied electric field.

This phenomenon can be understood that electrostatic induction causes the metal member 110, which is a conductor, to be in an electrostatic equilibrium state and to become an equipotential body. Due to such a phenomenon, directional polarization occurs such that the density of the free electrons 112 of the metal member surface 111 is reduced and the distribution of the free electrons 112 on the metal member surface 111 is changed.

As the density of the free electrons 112 distributed over the surface 111 of the metal member is reduced, the photons P of the laser beam LB are absorbed into the metal member 110 without being disturbed by the free electrons 112 on the surface 111 of the metal member, and then are absorbed by the bounding electrons in the metal member 110.

Furthermore, high-energy electrons absorbed into the metal member 110 very rapidly share energy with other electrons through electron-electron collision, and the electron energy is transmitted to the ions 115 and the lattice 116 through the electron-phonon interaction. Subsequently, the surface temperature of the metal member 110 rises while the electrons and the lattice system reach a thermal equilibrium. If the temperature of the metal member surface rises, the surface 111 of the metal member 110 starts to be softened.

If the laser transmissive mold 120 positioned above the metal member is moved down to press the surface 111 of the metal member 110 that is softened to be suitable for imprinting through the above-mentioned process, the micro- or nano-pattern of the mold 120 may be effectively transferred to the surface of the softened metal member 110.

FIG. 6 sequentially illustrates a process for imprinting a metal member surface using a device for imprinting a metal member in accordance with the present disclosure.

Referring to FIG. 6, the method for imprinting the metal member according to the present disclosure forms a capacitor electric field around a metal member 110 by applying current to electrode plates 131 and 132 positioned on opposite sides of the metal member 110 through an external power supply device, at step S210, prior to radiating the laser beam LB onto the surface of the metal member 110.

In this case, if the current is applied to the electrode plates 131 and 132 provided on the opposite sides of the metal member 110 through the external power supply device, one electrode plate 131 is charged with a positive (+) current and the other electrode plate 132 is charged with a negative (−) current, so a capacitor electric field is formed between both the electrode plates 131 and 132.

Further, if the capacitor electric field is formed between both the electrode plates 131 and 132, the free electrons 112 and the holes 113 in the metal member 110 are moved towards both the electrode plates 131 and 132 due to an attractive force generated by the electric field, to be rearranged and aligned on both side surfaces of the metal member 110, so the density of the free electrons 112 is remarkably reduced on the surface 111 of the metal member 110 into which the laser beam LB is incident.

As such, if the density of the free electrons is reduced on the surface 111 of the metal member 110 by forming the electric field, the surface of the metal member 110 is softened to be suitable for imprinting by radiating an IR band laser beam LB onto the surface 111 of the metal member 110 through the laser-beam generating device and heating the surface, at step S220.

In this case, due to a reduction in density of the free electrons 112 on the surface of the metal member 110, most of the laser beam LB incident into the surface of the metal member 110 is absorbed into the metal member 110 without being disturbed by the free electrons 112, so the temperature of the metal member 110 is increased by an electron-phonon interaction. Further, as the temperature of the metal member 110 increases, the surface 111 of the metal member is softened to be suitable for an imprinting operation.

After the surface 111 of the metal member 110 is softened to be suitable for imprinting through the above-mentioned process, the surface 111 of the softened metal member 110 is pressed by a laser transmissive mold 120 having a fine pattern of a micro- or nano-structure to form the fine pattern of the micro- or nano-structure on the surface 111 of the metal member 110, at step S230.

In this regard, if the metal member 110 is heated through a heater 140 prior to radiating the laser beam LB onto the surface 111 of the metal member 110, the operation of softening the surface 111 of the metal member 110 may be further promoted, so a time taken to radiate the laser beam LB may be shortened, and thereby a time required for the imprinting process may be greatly shortened.

As described above, the device and method for imprinting the metal member according to the present disclosure are configured such that the external electric field is applied to the periphery of the metal member 110 that is to be imprinted, to rearrange the free electrons 112 in the metal member 110, thereby reducing the density of the free electrons 112 on the metal member surface 111 and consequently increasing the absorptivity of the laser beam LB, and the fine pattern of the micro- or nano-structure can be effectively transferred to the surface of the metal member 110, which is heated and softened by the laser beam LB, using the laser transmissive mold 120.

In this case, the present disclosure is advantageous in that a large-area process is realized at low cost within a short period of time when the nano pattern is transferred to the metal member, by scanning the laser beam LB over the entire area of the metal member surface 111 for a short period of time while the laser transmissive mold 120 and the surface 111 of the metal member coming into contact with each other, in a state where the electric field is applied to the periphery of the metal member 110.

In particular, according to the present disclosure, it is possible to form a metal surface, such as a large-area metal plate or a large-area metal workpiece having a fine pattern, which has anti-bacteria, anti-icing, anti-biofouling, anti-corrosion, drag-reduction functions or combinations thereof.

In the case of imprinting glass as a target material through a laser transmissive mold as in the related art, the laser is absorbed well by a glass surface, so the imprinting operation may be easily performed. However, when a target material is a metal material, the laser is not absorbed well by a metal surface, so the imprinting operation may not be easily performed unlike the glass.

In particular, a metal thermal imprinting process using an IR laser transmissive mold is problematic in that the reflectance of a metal material is high in an IR region, so IR energy is not absorbed by a metal surface, and consequently the metal surface does not reach temperature required for imprinting. In contrast, a device and a method for imprinting a metal member according to the present disclosure is advantageous in that an electric field is applied to the periphery of the metal member, so the IR laser absorptivity is increased on the surface of the metal member and thereby a nano pattern structure can be easily transferred to the surface of the metal member with an IR laser transmissive mold.

While the present disclosure has been described with reference to preferred embodiments, it is apparent to those skilled in the art that these embodiments have been described for illustrative purposes, and various changes and modifications may be made without departing from the spirit and scope of the present disclosure as defined by the appended claims.

What is claimed is:

1. A device for imprinting a metal member using an external electric field and an IR band laser transmissive mold, the device comprising:
a laser-beam generating device spaced apart from a surface of the metal member that is to be imprinted, and generating a laser beam of an IR band to radiate the laser beam onto the surface of the metal member;
an electric-field forming device forming an electric field between both side surfaces of the metal member perpendicular to a direction in which the laser beam is incident; and
a mold made of a material through which the laser beam may be transmitted, having on a surface thereof a fine pattern to form the fine pattern on the surface of the metal member, and performing an imprinting operation while coming into contact with the surface of the metal member that is softened by irradiation of the laser beam.

2. The device of claim 1, wherein the laser beam radiated onto the surface of the metal member is an IR band CO₂ laser beam.

3. The device of claim 1, wherein the fine pattern formed on the surface of the mold is a fine pattern of a micro- or nano-scale structure.

4. The device of claim 1, wherein the electric-field forming device comprises:
a pair of electrode plates arranged on both side surfaces of the metal member to face each other, and charged through a current applied by an external device to form an electric field around the metal member;
a support plate spaced apart from the electrode plates to support the metal member; and
a support frame fixed on the support plate to support each of the electrode plates.

5. The device of claim 4, wherein the pair of electrode plates is disposed to be parallel to a direction in which the laser beam is incident.

6. The device of claim 4, further comprising:
a heater disposed between the metal member and the support plate to previously heat the metal member before the laser beam is incident.

7. The device of claim 4, wherein the support plate is formed of a heat insulating material.

8. A method for imprinting a metal member using an external electric field and an IR band laser transmissive mold, the method comprising:
forming an electric field between both side surfaces of the metal member that is to be imprinted;
softening a surface of the metal member to be suitable for imprinting, by generating an IR band laser beam from a laser-beam generating device spaced apart from the surface of the metal member and then radiating the laser beam onto the surface of the metal member perpendicular to both side surfaces of the metal member; and
forming a fine pattern on the surface of the metal member by pressing the softened metal member surface with the laser transmissive mold having a fine pattern.

9. The method of claim 8, wherein the laser beam radiated onto the surface of the metal member is an IR band CO₂ laser beam.

10. The method of claim 8, wherein the fine pattern formed on the mold is a fine pattern of a micro- or nano-scale structure.

11. The method of claim 8, further comprising:
previously heating the metal member through a heater, before the laser beam is radiated onto the surface of the metal member.
